(19) United States
(12) Patent Application Publication
(10) Pub. No.: US 2012/0243553 A1
(43) Pub. Date: Sep. 27, 2012

(54) 40 GIGABIT ATTACHMENT UNIT INTERFACE (XLAUI) LANE ELECTRICAL INTERFACE TO REPLACE 10 GIGABIT XFP (XFI) IN 10GB/S CHANNEL APPLICATIONS

(76) Inventor: Ricardo O. Rabinovich, Tarzana, CA (US)

(21) Appl. No.: 13/053,426

(22) Filed: Mar. 22, 2011

(51) Int. Cl. H04L 12/66; H05K 3/00

(52) U.S. Cl. 370/463; 29/829

(57) ABSTRACT

The preferred device (e.g. printed circuit board or PCB) includes a XLAUI bi-directional lane link (i.e. ¼ XLAUI channel) inserted onto the printed circuit board between a PHY integrated circuit and an Ethernet media access control (MAC) processor. This XLAUI bi-directional lane link replaces the electrical XFI channel in 10 Gb/s interconnects between integrated circuits on a PCB. The preferred methodology includes inserting a bi-directional 10 Gb/s XLAUI lane link onto a printed circuit board for use in 10 Gb/s interconnects between a PHY integrated circuit and a MAC processor.

### CROSS REFERENCE TO RELATED APPLICATIONS

This United States non-provisional patent application does not claim priority to any United States provisional patent application or any foreign patent application.

### FIELD OF THE DISCLOSURE

The disclosures made herein relate generally to the telecommunications industry. The invention discussed herein is in the general classification of a device and methodology for establishing a 40 Gigabit (Gb) attachment unit interface (XLAUI) lane electrical interface to replace a 10 Gigabit XFP (XFI) in 10 Gb/s channel applications.

### BACKGROUND

This section introduces aspects that may be helpful in facilitating a better understanding of the invention. Accordingly, the statements of this section are to be read in this light and are not to be understood as admissions about what is in the prior art or what is not in the prior art.

Certain terminology will be used throughout this application and merit a brief explanation.

XFP is a standard that specifies the mechanical and electrical interface specifications between an optical transceiver module and a physical layer (PHY) device. It is desirable for devices to be XFP compliant to ensure consumers can use transceivers/devices from various manufacturers. Various XFP compliant transceiver modules, connectors and test printed circuit boards (PCB) boards are commercially available. As the name suggests, a transceiver is a device having both transmitter and receiver circuitry.

A printed circuit board (PCB) utilizes traces to electrically connect different electronic components. The traces are conductive pathways of copper used for relaying electrical signals. The traces are laminated onto a non-conductive substrate to form the PCB. The non-conductive substrate could include glass or other insulating materials.

Typically, the PCB is formed by using a blank PCB with a layer of copper covering the entire substrate and removing all the undesired copper to form the copper traces. However, copper traces can also be added to the substrate to form the PCB in certain cases.

A variety of dielectrics can be utilized to create different insulating values to accommodate the requirements of the circuit. FR-4 is the designation for glass reinforced epoxy laminate sheets and PCBs. FR408 is a high performance FR-4 epoxy laminate and prepeg system designed for advanced circuitry applications. It has a low dielectric constant and low dissipation factor that allow it to be used with circuits requiring faster signal speeds or improved signal integrity. FR408 is compatible with most FR-4 processes.

Vias are holes through a PCB. The walls of the vias are copper plated to electrically connect the conducting layers of the PCB. Electronic components may be attached to pads on the outer surfaces of the PCB. Component leads can be fixed to the board via soldering. Differential pairs are conductors found on PCBs for carrying differential signals.

A line card is simply an electronic circuit on a PCB that interfaces with the telecommunications lines of subscribers to the telecommunications access network.

Presently, there are two re-timed 10 Gb/s channels: (1) the XFI interface defined in the INF-8077i rev. 4.5 specification published on Aug. 31, 2005; and (2) the XLAUI interface, a 4×10 Gb/s interface targeted to transmit Ethernet frames at 40 Gb/s concatenated in four 10 Gb/s channels. This XLAUI interface is defined in Annex 83A of the Institute of Electrical and Electronic Engineers (IEEE) standard (STD) 802.3ba-2010 (40 GBASE/100 GBASE Ethernet) officially published on Jun. 22, 2010 as an annex to the IEEE802.3 Ethernet Standard.

XAUI is a standard that extends 10 Gigabit Media Independent Interfaces between the MAC and PHY layer of 10 Gigabit Ethernet. A XAUI interface has four lanes or bi-directional links (i.e. differential pairs) that permit 3.125 Gb/s using 8B/10B encoding. XAUI can be used to extend the physical separation possible between MAC and PHY components in a 10 Gigabit Ethernet system distributed across a circuit board. XAUI is intended to be used between integrated circuits (ICs) which utilize traces on PCBs to permit greater distance between MAC and PHY components.

Integrated Circuits (ICs) are miniaturized electronic circuits that predominantly utilize semiconductor devices that are manufactured on a thin substrate of semiconductor material.

XLAUI interfaces follow the concept of the XAUI interface but, due to the bit rate required, use the 64B/66B encoding, rather than the 8B/10B encoding. An XLAUI channel uses four lanes (i.e. four bi-directional links with a single lane being referred to herein as a XLAUI bi-directional lane link or a XLAUI 10 Gb/s bi-directional lane link).

PHY is an abbreviation for the physical layer (i.e. layer 1) of the Open Systems Interconnection (OSI) model. A PHY connects a link layer device (i.e. a Media Access Controller (MAC)) to a physical medium such as an optical fiber or copper cable.

MAC is a sublayer of the Data Link Layer (i.e. layer 2) of the OSI model. It provides addressing and channel access control. The hardware that implements the MAC is the Medium Access Controller. The MAC sub-layer acts as an interface between the Logical Link Control sublayer and the network's physical layer.

Repeaters are electronic devices that permit signals to travel longer distances by retransmitting a received signal at a higher level or power.

Link aggregation permits multiple network cables and ports to run in parallel to increase the link speed and availability in a computer network.

Currently, re-timed 10 Gb/s interfaces between ICs use the XFI electrical interface which defines a maximum insertion loss (i.e. attenuation) of 5.7 dB at 5.156 GHz (i.e. half the channel bit rate of 10.3125 Gb/s). This specification provides, even on a sophisticated material such as a FR408 printed circuit board, a maximum theoretical channel length of about 7.5 inches (i.e. 0.5 dB/inch with 2 dB removed to compensate for other impairments). Expensive channel 10 Gb/s repeaters are often inserted to address the problem of limited channel length. XFI utilizes a single lane (i.e. bi-directional link or differential pair) running at 10.3125 Gb/s when using a 64B/66B encoding scheme.

There is a need for a device and methodology that efficiently, reliably and affordably permit establishing a 40 Gigabit attachment unit interface (XLAUI) lane electrical interface where each XLAUI bi-directional lane link can replace a 10 Gigabit XFP (XFI) in 10 Gb/s channel applications to extend channel length.

### SUMMARY OF THE DISCLOSURE

The preferred device (e.g. a PCB) includes a XLAUI bi-directional lane link (i.e. a ¼ XLAUI channel). This XLAUI bi-directional lane link replaces the electrical XFI channel in 10 Gb/s interconnects between ICs.

The preferred device includes a PHY IC and MAC processor with the XLAUI bi-directional lane link between the PHY IC and MAC processor.

The preferred methodology for manufacture includes inserting a XLAUI bi-directional lane link on a PCB for use in 10 Gb/s interconnects between ICs.

The preferred methodology of use includes utilizing a PCB with a XLAUI bi-directional lane link that connects a PHY IC and a MAC processor.

Under some applications, embodiments may provide a device and method that are relatively inexpensive to implement to establish a XLAUI lane electrical interface to replace a 10 Gigabit XFP (XFI) in 10 Gb/s channel applications.

Under some applications, embodiments may provide a device and method that are not operationally complex that allow the establishment of a XLAUI electrical interface to replace multiple Gigabit XFP (XFI) in 10 Gb/s channel applications.

Under some applications, embodiments may provide a device and method that efficiently allow the establishment of a XLAUI lane electrical interface to replace a 10 Gigabit XFP (XFI) in 10 Gb/s channel applications.

Under some applications, embodiments may provide a reliable device and method that allow the establishment of a XLAUI lane electrical interface to replace a 10 Gigabit XFP (XFI) in 10 Gb/s channel applications.

Under some applications, embodiments may provide a device and method that are relatively inexpensive to manufacture and/or deploy that permit the establishment of a XLAUI lane electrical interface to replace a 10 Gigabit XFP (XFI) in 10 Gb/s channel applications.

Under some applications, embodiments may provide a device and method that provide cost savings by avoiding expensive repeaters and associated clocking circuitry in extended reach channel applications.

Under some applications, embodiments may provide a device and method that allow use of less PCB real estate, lower power and lower latency in extended channel applications.

### BRIEF DESCRIPTION OF THE DRAWINGS

Some embodiments of apparatus and/or methods of the present invention are now described, by way of example only, and with reference to the accompanying drawings, in which:

FIG. 1 depicts the preferred embodiment of the device (e.g. PCB) having a bi-directional 10 Gb/s XLAUI lane link between an Ethernet Media Access Control (MAC) processor and a Physical IC Driver (PHY).

FIG. 2 depicts a graph that compares the insertion loss as a function of the frequency between the XFI interface specification and the XLAUI lane interface specification.

FIG. 3 depicts the method of manufacture of the preferred embodiment for establishing a XLAUI lane electrical interface to replace a 10 Gigabit XFP (XFI) in 10 Gb/s channel applications.

FIG. 4 depicts the method of use of the preferred embodiment for establishing a XLAUI lane electrical interface to replace a 10 Gigabit XFP (XFI) in 10 Gb/s channel applications.

### DETAILED DESCRIPTION OF THE DRAWINGS

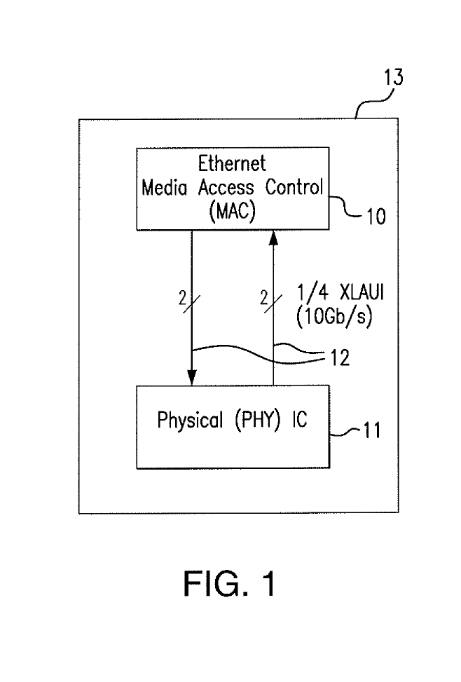

FIG. 1 depicts the preferred embodiment of the device (e.g. PCB) having a bi-directional 10 Gb/s XLAUI lane link between an Ethernet Media Access Control (MAC) processor and a Physical IC Driver (PHY).

The preferred embodiment of the PCB 13 includes a PHY IC 11 operatively connected to a MAC processor 10. A XLAUI 10 Gb/s bi-directional lane link 12 is located between and operatively connects the PHY IC 11 and MAC processor 10. The XLAUI 10 Gb/s bi-directional lane link 12 replaces the electrical XFI channel that is traditionally used in 10 Gb/s interconnects between ICs on PCBs.

The PHY IC 11 may perform conventional network interface functions, including the reception and transmission of Ethernet symbol streams. When receiving a symbol stream from the associated communications link, electrical or optical signals from the communications link are converted by the PHY IC 11 to a byte stream which can then be transmitted to the MAC processor 10.

In the transmit mode, the PHY IC 11 converts a byte steam from the MAC processor 10 to electrical or optical signals appropriate for the medium to which it is connected.

The MAC processor 10 performs conventional network interface functions, including the reception and transmission of Ethernet frames. In reception mode, the MAC processor 10 performs various functions including: (a) MAC frame parsing for extracting from the Ethernet Type/Length field, the encapsulated protocol type, the frame priority, the user priority of virtual local area network (VLAN) tagged frames, and the type of service (TOS) byte of IP frames with precedence or DiffServe mapping; (b) error checking using the frame check sequence (FCS) value of received data as well as packet de-encapsulation; and (c) asymmetric and symmetric flow control including the acceptance of flow control frames to discontinue frame transmission or pause frame transmission by a network neighbor.

In the transmission mode, frames undergo local processing at the MAC processor 10. The MAC processor 10 may perform functions, including: (a) collision handling; (b) access control to the communications medium in accordance with the carrier sense multiple access with collision detection (CSMA/CD) transmission protocol; (c) frame check sequence (FCS) value generation; (d) encapsulation; and (e) transmit deferral.

The PCB 13 of the preferred embodiment replaces the XFI channel electrical definition with the XLAUI lane electrical specification to improve insertion loss. Insertion loss is the loss of signal power when a device is placed in a transmission line in a telecommunications network. Insertion loss is usually expressed in decibels. In telecommunications applications, a decibel is typically ten times the logarithm to base ten (10) of the ratio of two power quantities.

The XLAUI single channel electrical specification defines a maximum insertion loss of about 10.5 dB at a frequency of 5.156 GHz (gigahertz). This means that there is an extra maximum insertion loss of 4.8 dB (i.e. 10.5 dB according to the XLAUI single channel specification—5.7 dB according to the XFI channel specification) over the XFI channel electrical specification. This allows a theoretical extension of the lane links by approximately 6.4 inches (i.e. (4.8 dB-1.6 dB for impairments)/0.5 dB per inch) compared to the theoretical channel length of approximately 7.5 inches (i.e. (5.7 dB-2 dB for impairments)/0.5 dB per inch) when the XFI channel electrical specification is utilized. This permits a theoretical lane link length of approximately fourteen (14) inches when using FR408 materials with the XLAUI single channel electrical specification. However, this theoretical maximum length may not account for all interconnect impairments.

In actual testing, the extra maximum insertion loss of 4.8 dB between the XLAUI single channel electrical specification and the XFI channel electrical specification has indeed allowed an extension of the lane links by 6.4 inches (i.e. 4.8 dB/0.76 dB per inch) compared to the channel length of approximately 7.5 inches when the XFI channel electrical specification is utilized. This has permitted a total lane link length of approximately 13.8 inches when using FR 408 materials with the XLAUI single channel electrical specification.

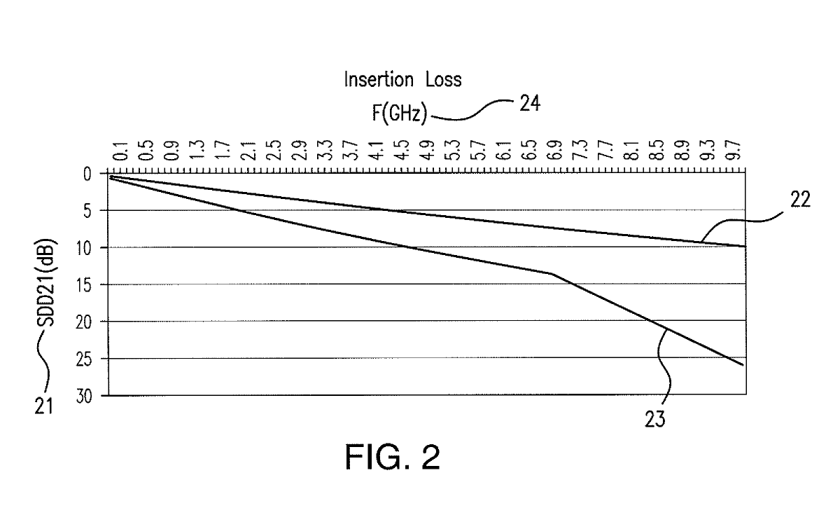

FIG. 2 depicts a graph that compares the insertion loss in decibels (dB) 21 as a function of the frequency in gigahertz (GHz) 24 between the XFI interface specification and the XLAUI lane electrical interface specification.

A passive channel will always have an insertion loss between the x-axis and the mask line. A higher mask curve necessitates a lower maximum insertion loss. FIG. 2 shows that the XFI interface specification has a higher mask curve as compared to the XLAUI lane interface specification.

As recited in INF-8077i, Revision 4.5-10 Gigabit Small Form Factor Pluggable Module, the XFI maximum allowable insertion loss is defined with the following equation and graphed in line 22:

SDD21(dB)=(−0.1−0.78×\sqrt{f}−0.74×f)

The XFI line 22 depicts a relatively low maximum allowable insertion loss at the lower frequencies (around 0.1 GHz) of the graph. The graph reveals that the XFI maximum allowable insertion loss increases to around 10 dB at around 10.3125 GHz. The XFI line 22 depicts a maximum allowable insertion loss of 5.7 dB at a frequency of 5.156 GHz (gigahertz) (i.e. Nyquist frequency).

As recited in IEEE Std 802.3ba-2010, MAC Parameters, Physical Layers and Management Parameters for 40 Gb/s and 100 Gb/s Operation, the XLAUI maximum allowable insertion loss is defined with the following equation and graphed in line 23:

$$Insertion\_loss ( f ) < \{ \begin{matrix}0.15 + 1.39 √ f + 1.4 f & 0.01 \leq f < 7 \\ - 15.86 + 4.2 f & 7 \leq f \leq 11.1\end{matrix} \} ( dB )$$

The XLAUI line 23 also only depicts a relatively low maximum insertion loss at the lower frequencies (i.e. around 0.1 GHz) of the graph. However, the XLAUI line 23 reveals that the XLAUI maximum allowable insertion loss increases more dramatically than the XFI maximum allowable insertion loss as the frequencies increase. In particular, the XLAUI line 23 shows a maximum allowable insertion loss of 10.5 dB at a frequency of 5.156 GHz (gigahertz). The XLAUI line 23 depicts an even more pronounced increase in the maximum insertion loss around seven (7) GHz.

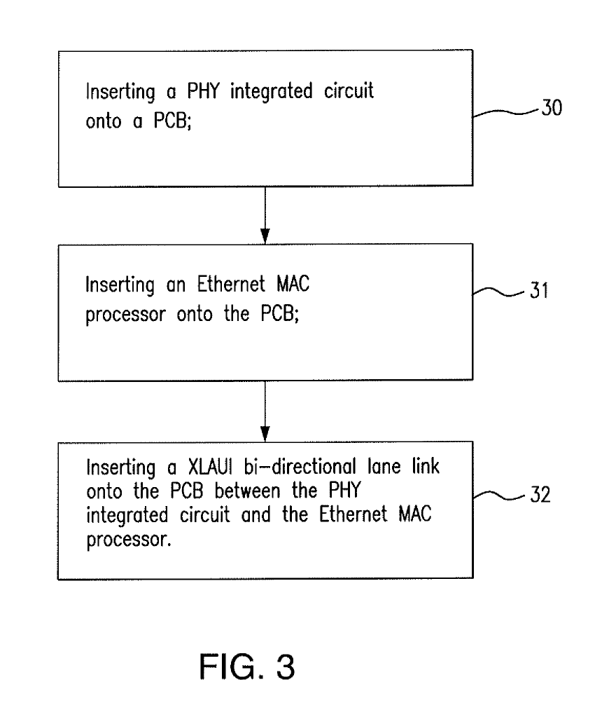

FIG. 3 depicts the method of manufacture of the preferred embodiment for establishing a XLAUI lane electrical interface to replace a 10 Gigabit XFP (XFI) in 10 Gb/s channel applications.

The preferred methodology includes inserting a PHY integrated circuit onto a PCB 30; inserting an Ethernet media access control (MAC) processor onto the PCB 31; and inserting a XLAUI bi-directional lane link (i.e. ¼ XLAUI channel) onto the PCB for use in 10 Gb/s interconnects between the Ethernet MAC processor and the PHY integrated circuit 32.

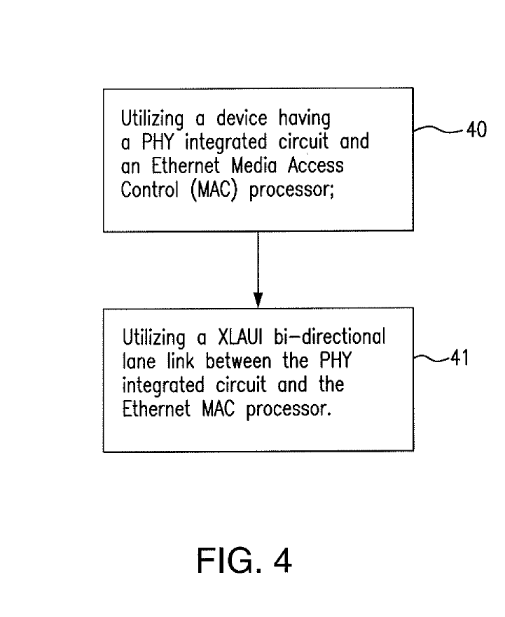

FIG. 4 depicts the method of use of the preferred embodiment for establishing a XLAUI lane electrical interface to replace a 10 Gigabit XFP (XFI) in 10 Gb/s channel applications.

The preferred methodology includes utilizing a device having a PHY integrated circuit and an Ethernet media access control (MAC) processor 40; and utilizing a XLAUI bi-directional lane link between the PHY integrated circuit and the Ethernet MAC processor 41.

A person of skill in the art would readily recognize that the order of the steps in the above-described methods is not necessarily critical.

It will be recognized by those skilled in the art that changes or modifications may be made to the above-described embodiments without departing from the broad inventive concepts of the invention. It should therefore be understood that this invention is not limited to the particular embodiments described herein, but is of the invention as set forth in the claims.

What is claimed is:

1. A device for use in 10 Gb/s channel applications comprising:
(a) a PHY integrated circuit;
(b) an Ethernet media access control (MAC) processor; and
(c) a XLAUI 10 Gb/s bi-directional lane link between the PHY integrated circuit and the Ethernet MAC processor.

2. The device of claim 1 wherein the device is a printed circuit board.

3. The device of claim 2 wherein the printed circuit board is a FR408 printed circuit board.

4. The device of claim 1 wherein the XLAUI 10 Gb/s bi-directional lane link between the PHY integrated circuit and the Ethernet MAC processor is greater than 7.5 inches in length.

5. The device of claim 1 wherein the XLAUI 10 Gb/s bi-directional lane link between the PHY integrated circuit and the Ethernet MAC processor is greater than 7.5 inches in length but less than fourteen (14) inches in length.

6. A method of manufacturing a device for use in 10 Gb/s channel applications comprising the steps of:
(a) inserting a PHY integrated circuit onto the device;
(b) inserting an Ethernet media access control (MAC) processor onto the device; and
(c) inserting a XLAUI 10 Gb/s bi-directional lane link onto the device between the PHY integrated circuit and the Ethernet MAC processor.

7. The method of claim 6 wherein the device is a printed circuit board.

8. The method of claim 7 wherein the printed circuit board is a FR408 printed circuit board.

9. The method of claim 6 wherein the XLAUI 10 Gb/s bi-directional lane link between the PHY integrated circuit and the Ethernet MAC processor is greater than 7.5 inches in length.

10. The method of claim 6 wherein the XLAUI 10 Gb/s bi-directional lane link between the PHY integrated circuit and the Ethernet MAC processor is less than fourteen (14) inches in length.

11. A method of using a device in 10 Gb/s channel applications comprising the steps of:
(a) utilizing a device having a PHY integrated circuit and an Ethernet media access control (MAC) processor; and
(b) utilizing a XLAUI 10 Gb/s bi-directional lane link between the PHY integrated circuit and the Ethernet MAC processor.

12. The method of claim 11 wherein the device is a printed circuit board.

13. The method of claim 12 wherein the printed circuit board is a FR408 printed circuit board.

14. The method of claim 11 wherein the XLAUI 10 Gb/s bi-directional lane link between the PHY integrated circuit and the Ethernet MAC processor is greater than 7.5 inches in length.

15. The method of claim 11 wherein the XLAUI 10 Gb/s bi-directional lane link between the PHY integrated circuit and the Ethernet MAC processor is less than fourteen (14) inches in length.
